(19) United States
(12) Patent Application Publication
(10) Pub. No.: US 2014/0252619 A1
(43) Pub. Date: Sep. 11, 2014

(54) INTERCONNECT STRUCTURE THAT AVOIDS INSULATING LAYER DAMAGE AND METHODS OF MAKING THE SAME

(71) Applicant: Taiwan Semiconductor Manufacturing Company, Ltd., (US)

(72) Inventors: Bo-Jiun Lin, Jhubei City (TW); Hai-Ching Chen, Hsin-Chu (TW); Tien-I Bao, Dayuan Township (TW)

(73) Assignee: TAIWAN SEMICONDUCTOR MANUFACTURING COMPANY, LTD., Hsin-Chu (TW)

(21) Appl. No.: 13/790,850

(22) Filed: Mar. 8, 2013

(51) Int. Cl. H01L 21/768; H01L 23/532

(52) U.S. Cl. CPC H01L 21/7685; H01L 23/53238
USPC 257/751; 438/627

(57) ABSTRACT

A method for forming an interconnect structure includes forming an insulating layer on a substrate. A damascene opening is formed through a thickness portion of the insulating layer. A diffusion barrier layer is formed to line the damascene opening. A conductive layer is formed overlying the diffusion barrier layer to fill the damascene opening. A carbon-containing metal oxide layer is formed on the conductive layer and the insulating layer.

### BACKGROUND

In forming damascene structures in integrated circuit manufacturing processes, the surface condition of the damascene opening is critical for achieving acceptable adhesion and coverage of overlying layers. The damascene opening, for example a dual damascene opening is formed in an inter-metal dielectric (IMD) insulating layer by a series of photolithographic patterning and etching processes, followed by formation of a barrier layer and overlying metal, e.g., copper, seed layer to promote a copper electro-chemical plating (ECP) deposition process.

Increasingly, low-K IMD layers are required to reduce signal delay and power loss effects as integrated circuit devices are scaled down. One way this has been accomplished has been to introduce porosity or dopants into the IMD layer. In particular, incorporation of low-K materials with dielectric constants less than about 3.0 has become standard practice as semiconductor feature sizes have diminished to less than 0.2 microns. As feature sizes decrease below about 45 nm, for example including 28 nm and less than 15 nm critical dimension technology materials with dielectric constants less than about 2.0 will be required. However, to improve the electromagnetic performance of the device a plasma treatment such as, for example chemical vapor deposition (CVD) or atomic layer deposition (ALD) is often used on the low-K IMD layers. The plasma treatment, however usually causes damage to the low-K material thereby reducing the performance of the device. This problem at least has created manufacturing limitations that must be overcome to form reliable copper damascenes in smaller critical dimension technologies.

### BRIEF DESCRIPTION OF DRAWINGS

Embodiments of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method of forming an interconnect structure according to various embodiments of the present disclosure.

FIGS. 2-6 are cross-sectional side views of an exemplary damascene structure at various stages of manufacture in accordance with various embodiments of the present disclosure.

### DETAILED DESCRIPTION

In the following description, specific details are set forth to provide a thorough understanding of embodiments of the present disclosure. However, one having an ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

Although the present disclosure is explained by reference to an exemplary dual damascene formation process, it will be appreciated that the method of the present disclosure applies generally to the formation of damascenes including single vias and trench lines extending through single or multiple IMD layers. While embodiments of the method is particularly advantageous for forming copper damascenes in porous low-K dielectrics, it will be appreciated that the method may be applied to the formation of other metal damascenes and other dielectric insulating layers.

By the term damascene is meant any damascene interconnect structure e.g., both single and dual damascenes, including vias, contact openings, and trench lines. Further, the term “copper” will be understood to include copper and alloys thereof

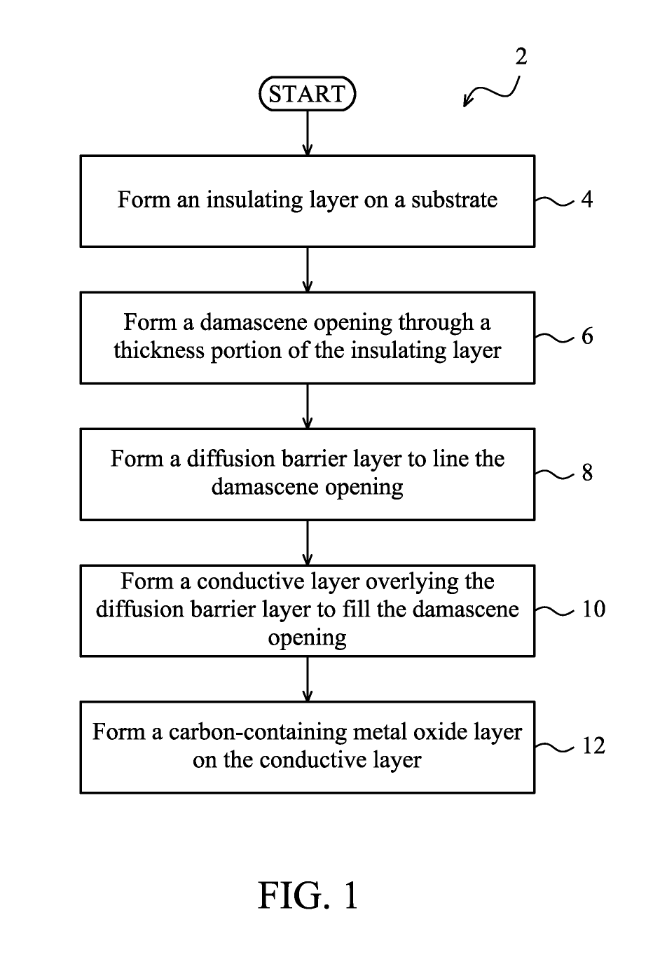

FIG. 1 is a flowchart of a method 2 for forming an interconnect structure according to various aspects of the present disclosure. Referring to FIG. 1, the method includes block 4, in which an insulating layer is formed on a substrate. The method 2 includes block 6, in which a damascene opening is formed through a thickness portion of the insulating layer. The method 2 includes block 8, in which a diffusion barrier layer is formed to line the damascene opening. The method 2 includes block 10, in which a conductive layer is formed to overly the diffusion barrier layer to fill the damascene opening. The method 2 includes block 12, in which a carbon-containing metal oxide layer is formed on the conductive layer and the insulating layer.

It is understood that additional processes may be performed before, during, or after the blocks 4-12 shown in FIG. 1 to complete the fabrication of the interconnect structure of a semiconductor device, but these additional processes are not discussed herein in detail for the sake of simplicity.

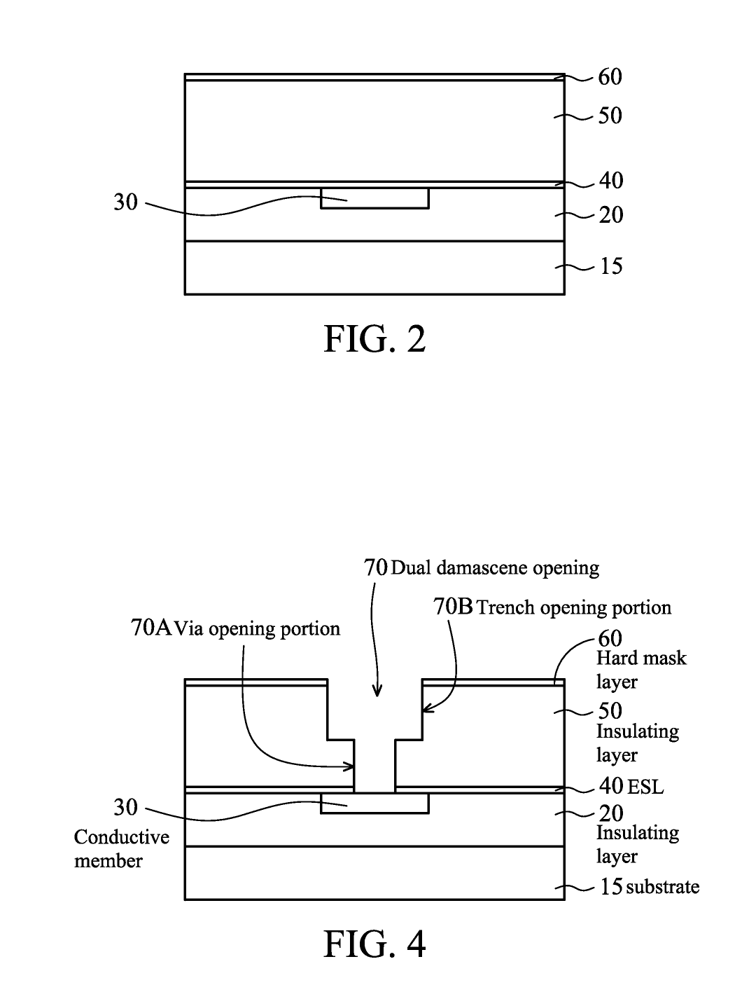

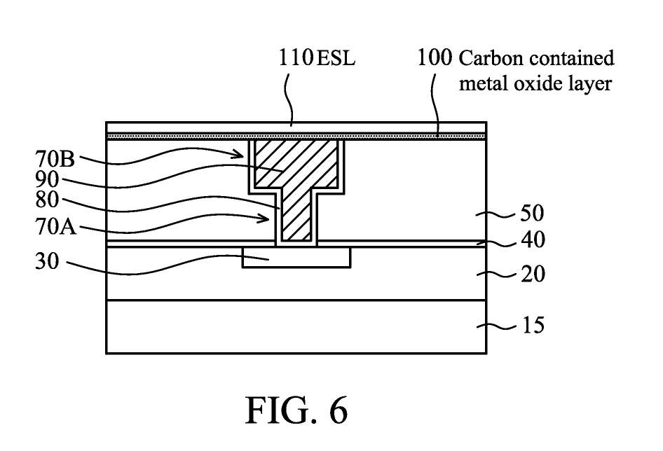

FIGS. 2-6 are cross-sectional views of an exemplary damascene structure at various stages of manufacture according to embodiments of the method 2 of FIG. 1. It is understood that FIGS. 2-6 have been simplified for a better understanding of the inventive concepts of the present disclosure. It should be appreciated that the materials, geometries, dimensions, structures, and process parameters described herein are exemplary only, and are not intended to be, and should not be construed to be, limiting to the invention claimed herein. Many alternatives and modifications will be apparent to those skilled in the art, once informed by the present disclosure.

Referring to FIG. 2, a substrate 15 including for example conductive member 30 is formed in a dielectric insulating layer 20 by conventional processes known in the micro-electronic integrated circuit manufacturing art. The conductive member 30 electrically connects to an underlying semiconductor device or conductive line (not shown). Thereafter, an overlying first etching stop layer 40, for example silicon nitride (e.g., SiN, Si₃N₄) or silicon carbide (e.g., SiC) is deposited on the dielectric insulating layer 20 and the conductive member 30 to a thickness of about 50 Angstroms to about 300 Angstroms by conventional chemical vapor deposition (CVD) processes, for example, plasma-enhanced chemical vapor deposition (PECVD) or LPCVD.

Still referring to FIG. 2, formed over the first etching stop layer 40 is dielectric insulating layer 50, for example an inter-metal dielectric (IMD) layer, formed of a low-K dielectric material, for example a silicon oxide based material having a porous structure. By the term “low-K dielectric” is meant having a dielectric constant less than about 2.0. In some embodiments, the material for the dielectric insulating layer 50 is a carbon-doped silicon dioxide material, fluorinated silicate glass (FSG), organic silicate glass (OSG), fluorine doped silicon oxide, spin-on glasses, silsesquioxane, benzocyclobutene (BCB)-based polymer dielectrics and any silicon containing low-k dielectric. The dielectric insulating layer 50, in an exemplary embodiment is formed by a CVD process, for example LPCVD or PECVD including organo-siloxane precursors such as cyclo-tetra-siloxanes such as tetramethylcyclotetrasiloxane, octamethylcyclotetrasiloxane, and decamethylcyclopentasiloxane may be suitably used to form the IMD layer portion 50. It will be appreciated that inorganic or organic spin-on glass (SOG) may also be used, for example including organo-silane or organo-siloxane precursors which are spun on the substrate by conventional methods followed by a curing process including optional post curing thermal and plasma treatments.

Although not shown, in some embodiments, a middle etch stop layer, for example formed of silicon nitride, silicon oxynitride, silicon carbide, or silicon oxycarbide maybe formed in the middle portion of IMD layer 50 to separate an upper trench line portion and a lower via portion of the IMD layer 50 in a completed dual damascene structure.

Still referring to FIG. 2, in some embodiments, one or more hardmask/ARC layers, e.g., layer 60, preferably a single inorganic layer functioning as both a hard mask and a bottom anti-reflective coating (ARC), for example formed of silicon oxynitride, or silicon oxycarbide, is provided over the IMD layer 50 at an appropriate thickness, to minimize light reflectance from the IMD layer surface in a subsequent photolithographic patterning process.

Referring now to FIG. 3, conventional photolithographic and etching processes are then carried out to form a dual damascene opening 70. For example, a first via opening is formed by first dry etching through the hardmask/ARC layer e.g., 60 followed by dry etching through the thickness of the IMD layer 50, using conventional dry (e.g., reactive ion etch) etching chemistries to form a via opening portion e.g., 70A, followed by a similar lithographic and etching process to form a trench opening portion, e.g., 70B, overlying one or more via openings e.g., 70A. In some embodiments, the dual damascene opening 70 is formed by a trench first dual damascene process.

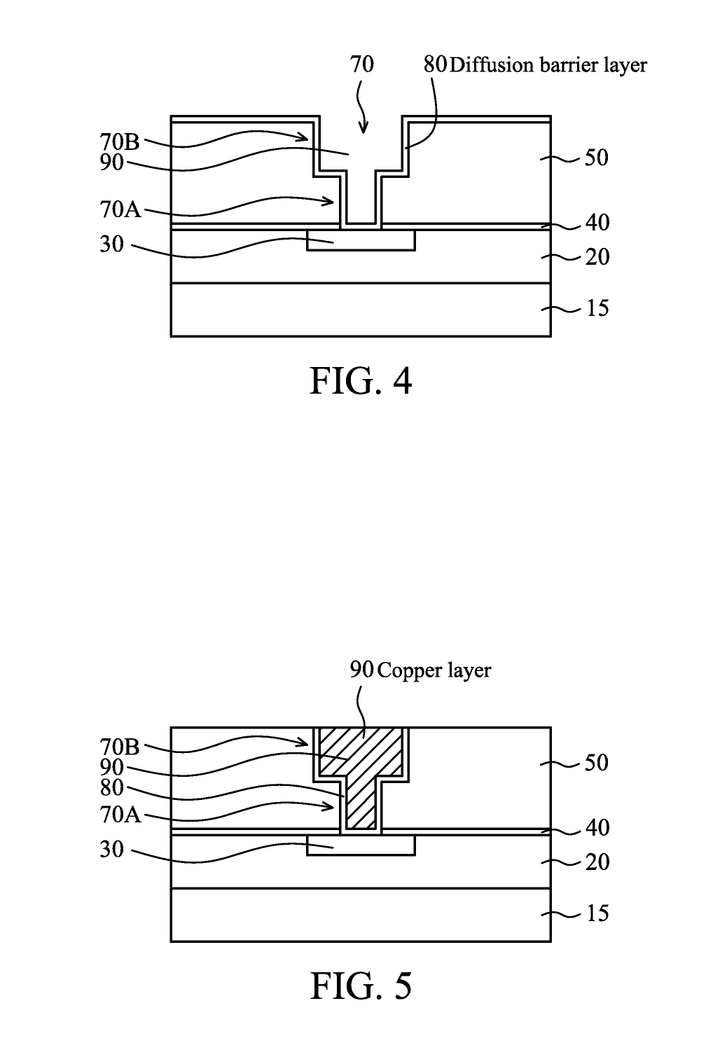

Referring to FIG. 4, a diffusion barrier layer 80 is blanket deposited to line damascene opening 70, including overlying an exposed portion of conductive member 30) at a bottom portion. The diffusion barrier layer 80 prevents copper from diffusing into surrounding materials such as insulating layer 50. In an exemplary embodiment, the diffusion barrier layer 80 is deposited by one of a CVD, PVD, ion metal plasma (IMP), or self-ionized plasma (SIP). In an exemplary embodiment, the diffusion barrier layer 80 includes silicon nitride. In some embodiments, the diffusion barrier layer 80 includes at least one layer of Ta, TaN, Ti, TiN, WN, Cr, CrN, TaSiN, TiSiN, and WSiN, deposited to a thickness of about 10 Angstroms to about 50 Angstroms. It is understood that the dimensions recited are merely examples, and will change with the down scaling of integrated circuits. In some other embodiments, the diffusion barrier layer 80 is Ta/TaN, TaN or TaSiN, or a dual layer of TaTaN.

Referring to FIG. 5, following formation of the diffusion barrier layer 80 in damascene opening 70, a conventional electro-chemical plating (ECP) process is carried out to blanket deposit a copper layer 90 filling the damascene opening 70. For example, for various types of damascenes, including single and dual damascenes, the copper layer 90 thickness may vary from about 500 Angstroms to about 1,500 Angstroms. It is understood that the dimensions recited are merely examples, and will change with the down scaling of integrated circuits. In other embodiments, the copper layer 90 is formed by electroless plating, electroplating, chemical vapor deposition, and/or physical vapor deposition. Following copper ECP deposition, a conventional planarization process, for example chemical mechanical planarization (CMP), is carried out to remove excess portion of copper layer 90 above the damascene opening level, diffusion barrier layer 80, and at least a portion of the hard mask layer 60, in some embodiments to complete the formation of the dual damascene.

In a conventional method of forming a damascene structure, in order to improve the electromagnetic performance of a device, typically a plasma treatment such as, for example chemical vapor deposition (CVD) or atomic layer deposition (ALD) is used on the low-K IMD layers. The plasma treatment may damage the low-k layer by bombarding the surface with plasma ions reducing the performance of the device. However, according to an aspect of the present disclosure, a plasma treatment is not required. Instead a carbon containing metal-oxide layer 100 is formed on the copper layer 90 and the insulating layer 50. Embodiments of the present disclosure having a carbon containing metal-oxide layer 100 provide one or more of the following advantages. First, the carbon in the carbon containing metal-oxide layer 100 provides good adhesion between the low-k insulating layer 50 and an upper etch stop layer 110 by acting as a glue layer between the low-k insulating layer 50 and the upper etch stop layer 110. Additionally, the metal-oxide in the carbon containing metal-oxide layer 100 improves the electromagnetic performance of the copper interconnect by providing good adhesion between the carbon containing metal-oxide layer 100 and an upper copper layer or metal line. Further, a plasma treatment is not required so there is no damage to the low-k layer.

In one embodiment, the carbon containing metal-oxide layer 100 is formed by a sol-gel process, a type of chemical procedure. In a sol-gel process, the colloidal “sol” (or solution) gradually evolves towards the formation of a gel-like diphasic substance having both a liquid phase and a solid phase. The diphasic substance can then be deposited on a substrate to form a film. According to an exemplary embodiment, a chemical compound aluminum-sec-butoxide ((Al(OBu²)), which provides the metal-oxide source is mixed with a chelating agent, one having a carbon source such as for example acetylacetone (AcAcH) or ethylacetoacetate to give rise to a precursor. In one embodiment, the aluminum-sec-butoxide is mixed with the acetylacetone for about 1 hour. The mixture may be sufficiently mixed as to give a homogenous solution. Then water (H₂O) is added to the mixture of aluminum-sec-butoxide and acetylacetone and the mixture is stirred for about 30 minutes. Nitric acid (HNO3) is thereafter added and the entire mixture is aged for approximately 24 hours to form a carbon contained metal oxide precursor. In some embodiments, other elements such as metals and/or metal oxides can be added into the precursor. The metal elements include, for example Al, Co, Mn, Cr, Fe, Au, Ag, Na, Ti, Zn, or Ca. According to one embodiment, the metal contained oxide precursor is deposited on the copper layer 90 and the insulating layer 50 by a spin-on or dip coating method. In an embodiment, the metal contained oxide precursor is spin-coated at approximately 1000 to approximately 2000 revolutions per minute (RPM) and has a thickness of about 50 Angstroms to about 500 Angstroms. In an embodiment, the spin-on process is followed by a post-treatment. Examples of post-treatments include ultra-violet (UV) curing.

Embodiments of the above-described method is but one way to form a precursor. It is understood that there are other ways to form precursors. The sol-gel approach to forming the carbon containing metal oxide layer 100 on the interconnect structure is a low-cost and low-temperature technique that allows for the fine control of the chemical composition, such as the number of carbon atoms present in the mixture. It is understood by those skilled in the art that the formation of the carbon containing metal oxide layer 100 is not limited to the sol-gel approach and that other methods are also available and further that the above embodiments are illustrative only and not intended to be limiting.

Following the deposition of the carbon contained metal oxide layer 100 on the copper layer 90 and the insulating layer 50, an upper etch stop layer 110 is deposited thereon. The upper etch stop layer 110 may be, for example silicon nitride (e.g., SiN, Si₃N₄) or silicon carbide (e.g., SiC). In an exemplary embodiment, the upper etch stop layer 110 is formed to a thickness of about 50 Angstroms to about 300 Angstroms by conventional chemical vapor deposition (CVD) processes, for example, plasma-enhanced chemical vapor deposition (PECVD) or LPCVD.

The present disclosure has described various exemplary embodiments. According to one embodiment, a method for forming an interconnect structure includes forming an insulating layer on a substrate. A damascene opening is formed through a thickness portion of the insulating layer. A diffusion barrier layer is formed to line the damascene opening. A conductive layer is formed overlying the diffusion barrier layer to fill the damascene opening. A carbon-containing metal oxide layer is formed on the conductive layer and the insulating layer.

According to another embodiment, a method for forming a copper damascene includes providing a substrate and forming a first insulating layer on the substrate, the first insulating layer having a conductive member. A first etch stop layer is formed on the first insulating layer and the conductive member. A second insulating layer is formed on the first etch stop layer. A hard mask layer is formed on the second insulating layer. The hard mask layer, the second insulating layer, and the first etch stop layer are sequentially etched to form a damascene opening in the second insulating layer. A diffusion barrier layer is formed to line the damascene opening and a conductive layer is formed overlying the diffusion barrier layer. The second insulating layer and the conductive layer are planarized to form a metal interconnect structure and a carbon-containing metal oxide layer is formed on the second insulating layer and the conductive layer.

According to yet another embodiment, a semiconductor device includes a substrate having a conductive member and an interconnect structure. The interconnect structure includes an insulating layer overlying the substrate, a conductive layer in the insulating layer electrically connecting the conductive member, and a carbon-containing metal oxide layer on the conductive layer and the insulating layer.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims.

1. A method for forming an interconnect structure, comprising:
forming an insulating layer on a substrate;
forming a damascene opening through a thickness portion of the insulating layer;
forming a diffusion barrier layer to line the damascene opening;
forming a conductive layer overlying the diffusion barrier layer to fill the damascene opening;
forming a carbon-containing metal oxide layer on the conductive layer and the insulating layer comprising using a sol-gel process, the sol-gel process comprising using a metal-oxide source and a carbon source; and
forming an etch stop layer over the carbon-containing metal oxide layer.

2. The method of claim 1, wherein the conductive layer is formed by an electro-chemical plating (ECP) process.

3. The method of claim 1, wherein the carbon-containing metal oxide layer is formed on the conductive layer and the insulating layer by a spin-on coating method.

4. (canceled)

5. The method of claim 1, wherein the sol-gel process comprises combining a chemical compound with a chelating agent having the carbon source.

6. The method of claim 5, wherein the chemical compound includes aluminum-sec-butoxide ((Al(OBu²)) and the chelating agent includes acetylacetone (AcAcH).

7. A method for forming a copper damascene, comprising:
forming a first insulating layer on a substrate, the first insulating layer having a conductive member;
forming a first etch stop layer on the first insulating layer and the conductive member;
forming a second insulating layer on the first etch stop layer;
forming a hard mask layer on the second insulating layer;
sequentially etching the hard mask layer, the second insulating layer, and the first etch stop layer to form a damascene opening in the second insulating layer;
forming a diffusion barrier layer to line the damascene opening;
forming a conductive layer overlying the diffusion barrier layer;
planarizing the second insulating layer and the conductive layer to form a metal interconnect structure;
forming a carbon-containing metal oxide layer on the second insulating layer and the conductive layer comprising using a sol-gel process, the sol-gel process comprising using a metal-oxide source and a carbon source; and
forming a second etch stop layer over the carbon-containing metal oxide layer.

8. The method of claim 7, wherein the conductive layer is formed by an electro-chemical plating (ECP) process to fill the damascene opening.

9. The method of claim 7, wherein the carbon-containing metal oxide layer is formed on the second insulating layer and the conductive layer by a spin-on coating method.

10-11. (canceled)

12. The method of claim 7, wherein the sol-gel process comprises combining a chemical compound with a chelating agent having the carbon source.

13. The method of claim 12, wherein the chemical compound includes aluminum-sec-butoxide ((Al(OBu²)) and the chelating agent includes acetylacetone (AcAcH).

14. A semiconductor device, comprising:
a substrate having a conductive member;
an interconnect structure, comprising:
an insulating layer overlying the substrate;
a conductive layer in the insulating layer electrically connecting the conductive member; and
a carbon-containing metal oxide layer on the conductive layer and the insulating layer, wherein the carbon-containing metal oxide layer has a thickness from about 50 Angstroms to about 500 Angstroms; and
an etch stop layer overlying and adjoining the carbon-containing metal oxide layer.

15. The semiconductor device of claim 14, wherein the conductive layer comprises copper or copper alloy and the conductive layer comprises a conductive line and a conductive plug, the conductive line located above the conductive plug.

16. The semiconductor device of claim 15, further comprising:
a diffusion barrier layer formed on a sidewall and a bottom surface of the conductive line and on a sidewall and a bottom surface of the conductive plug.

17. (canceled)

18. The semiconductor device of claim 15, wherein the insulating layer comprises a low-K dielectric insulator having a dielectric constant of less than about 2.0.

19. The semiconductor device of claim 18, wherein the insulating layer comprises SiOC.

20. The semiconductor device of claim 14, wherein the carbon-containing metal oxide layer comprises Al, Co, Mn, Cr, Fe, Au, Ag, Na, Ti, Zn, or Ca.
